(19) United States
(12) Patent Application Publication
(10) Pub. No.: US 2013/0037851 A1
(43) Pub. Date: Feb. 14, 2013

(54) SEMICONDUCTOR DEVICE

(71) Applicant: Ryohei GEJO, Hyogo-ken (JP)

(72) Inventor: Ryohei GEJO, Hyogo-ken (JP)

(73) Assignee: Kabushiki Kaisha Toshiba, Tokyo (JP)

(21) Appl. No.: 13/420,544

(22) Filed: Mar. 14, 2012

(30) Foreign Application Priority Data
Aug. 10, 2011 (JP) JP2011-175074

(51) Int. Cl. H01L 29/739; H01L 29/06

(52) U.S. Cl. 257/139; 257/493; 257/E29.201; 257/E29.007

(57) ABSTRACT

A semiconductor device including a base semiconductor layer of a first conductivity type, a cell portion including a diffusion region of a second conductivity type formed on a surface of the base semiconductor layer, a plurality of guard ring semiconductor layers of the second conductivity type formed on the surface of the base semiconductor layer, each guard ring semiconductor layer being formed to surround the cell portion, a plurality of first RESURF semiconductor layers of the first conductivity type provided on the surface of the base semiconductor layer inside the plurality of guard ring semiconductor layers and having a higher concentration than the base semiconductor layer and a second RESURF semiconductor layer of the first conductivity type provided on the surface of the base semiconductor layer between the outermost guard ring semiconductor layer and the EQPR semiconductor layer.

### CROSS REFERENCE TO RELATED APPLICATIONS

This application is based upon and claims the benefit of priority from the prior Japanese Patent Application No. 2011-175074 filed in Japan on Aug. 10, 2011; the entire contents of which are incorporated herein by reference.

### FIELD

The embodiments of the present invention relate to a semiconductor device.

### BACKGROUND

In recent years, power semiconductor elements such as an insulated gate bipolar transistor (IGBT) have been widely employed as switching elements used for an inverter circuit or power converter circuit configured to control a high withstand voltage and a large current.

In such a power semiconductor element, a withstand voltage is required corresponding to its use. In particular, a locally high electric field occurs at a termination portion of an element having a high withstand voltage of about 1000 V or more, thereby causing a breakdown. To prevent occurrence of the breakdown, normally, a semi-insulated polycrystalline silicon (SIPOS) layer, which is a semi-conductive film such as a polycrystalline silicon (poly-Si) layer is formed or a termination structure such as a reduced surface field (RESURF) structure, which is configured to stabilize an electric field of a surface, is provided on the surface of a semiconductor region with low impurity concentration serving as a depletion layer to enable compensation of a high-breakdown-voltage characteristic. However, the SIPOS structure reduces a switching response speed, while the RESURF structure makes it difficult to control concentration.

In general, by providing a guard ring layer at a termination portion of an element, a depletion layer formed may be uniformly extended at an outer circumference during application of a bias so that the intensity of an electric field can be reduced to maintain a withstand voltage. However, when the depletion layer excessively extends at an outer circumferential side of the guard ring layer, there is a risk of element destruction due to such as lattice defects of an outermost circumferential portion. Accordingly, in a high-withstand-voltage power semiconductor element, it has been requested to suppress element destruction of a peripheral edge and improve a withstand voltage.

### BRIEF DESCRIPTION OF THE DRAWING

FIG. 1 is a cross-sectional view of a termination structure of a semiconductor device according to a first embodiment.

FIG. 2 is a cross-sectional view of a termination structure of a semiconductor device according to a second embodiment.

FIG. 3 is a cross-sectional view of a termination structure of a semiconductor device according to a third embodiment.

FIG. 4 is a cross-sectional view of a termination structure of a semiconductor device according to a fourth embodiment.

FIG. 5 is a cross-sectional view of a termination structure of a semiconductor device according to a fifth embodiment.

FIG. 6A is a cross-sectional view of a termination structure of a semiconductor device according to a sixth embodiment.

FIG. 6B is a cross-sectional view of a termination structure of a semiconductor device according to a modified example of the sixth embodiment.

FIG. 7 is a top view of a termination structure of a semiconductor device according to a seventh embodiment.

### DETAILED DESCRIPTION

According to an aspect of the embodiments a semiconductor device is provided including: a base semiconductor layer of a first conductivity type;

a cell portion having a diffusion region of a second conductivity type formed on a surface of the base semiconductor layer;

a plurality of guard ring semiconductor layers of the second conductivity type formed on the surface of the base semiconductor layer, each guard ring semiconductor layer being formed to surround the cell portion;

an equivalent-potential ring (EQPR) semiconductor layer of the first conductivity type formed on a surface of an outer circumferential portion of the base semiconductor layer spaced apart from an outermost guard ring semiconductor layer of the plurality of guard ring semiconductor layers in an outer circumferential direction, the EQPR semiconductor layer having a higher concentration than the first semiconductor layer and a lower concentration than the guard ring semiconductor layer;

a plurality of first RESURF semiconductor layers of the first conductivity type provided on the surface of the base semiconductor layer inside the plurality of guard ring semiconductor layers, the plurality of first RESURF semiconductor layers having a higher concentration than the base semiconductor layer;

and a second RESURF semiconductor layer of the first conductivity type provided on the surface of the base semiconductor layer between the outermost guard ring semiconductor layer and the EQPR semiconductor layer, the second RESURF semiconductor layer having a higher impurity concentration than the first RESURF semiconductor layers.

According to another aspect of the embodiments a semiconductor device is provided including: a base semiconductor layer of a first conductivity type; a cell portion having a diffusion region of a second conductivity type formed on a surface of the base semiconductor layer; a plurality of guard ring semiconductor layers of the second conductivity type formed on the surface of the base semiconductor layer, each guard ring semiconductor layer being formed to surround the cell portion; an EQPR semiconductor layer of the first conductivity type formed on a surface of an outer circumferential portion of the base semiconductor layer spaced apart from an outermost guard ring semiconductor layer of the plurality of guard ring semiconductor layers in an outer circumferential direction, the EQPR semiconductor layer having a higher concentration than the first semiconductor layer and a lower concentration than the guard ring semiconductor layer; a plurality of first RESURF semiconductor layers of the second conductivity type provided on the surface of the base semiconductor layer inside the plurality of guard ring semiconductor layers, the plurality of first RESURF semiconductor layers having a higher concentration than the base semiconductor layer; and a second RESURF semiconductor layer of the second conductivity type provided on the surface of the base semiconductor layer between the outermost guard ring semiconductor layer and the EQPR semiconductor layer, the second RESURF semiconductor layer having a lower impurity concentration than the first RESURF semiconductor layer.

According to a further aspect of the embodiments a semiconductor device is provided including: a base semiconductor layer of a first conductivity type; a cell portion having a diffusion region of a second conductivity type formed on a surface of the base semiconductor layer; a plurality of guard ring semiconductor layers of the second conductivity type formed on the surface of the base semiconductor layer, each guard ring semiconductor layer being formed to surround the cell portion; an EQPR semiconductor layer of the first conductivity type formed on a surface of an outer circumferential portion of the base semiconductor layer spaced apart from an outermost guard ring semiconductor layer of the plurality of guard ring semiconductor layers in an outer circumferential direction, the EQPR semiconductor layer having a higher concentration than the first semiconductor layer and a lower concentration than the guard ring semiconductor layer; a plurality of first RESURF semiconductor layers of the second conductivity type provided on the surface of the base semiconductor layer inside the plurality of guard ring semiconductor layers, the plurality of first RESURF semiconductor layers having a higher concentration than the base semiconductor layer; and a second RESURF semiconductor layer of the first conductivity type provided on the surface of the base semiconductor layer between the outermost guard ring semiconductor layer and the EQPR semiconductor layer.

Hereinafter, the embodiments of the present invention will be described with reference to the appended drawings.

### First Embodiment

FIG. 1 is a cross-sectional view of a termination structure of a semiconductor device according to the present embodiment. As shown in FIG. 1, a cell portion 12 having a p-type diffusion region 12a is formed on a surface of an n⁻ base layer 11. In the cell portion 12, for example, a trench gate 12b and an n-type emitter layer 12c are formed such that the trench gate 12b is interposed between the diffusion region 12a and the n-type emitter layer 12c.

Furthermore, for example, three p-type guard ring layers 14a, 14b, and 14c are formed apart from a p-type RESURF region 13 formed around the cell portion 12 to surround the cell portion 12. The three p-type guard ring layers 14a, 14b, and 14c are formed apart from one another. The number of the p-type guard ring layers is not limited to 3, and the number and dimensions of the p-type guard ring layers are appropriately selected in consideration of a required withstand voltage and the like. Also, an n⁺⁺-type equivalent-potential ring (EQPR) layer 15 is formed apart from an outer circumference of the p-type guard ring layer 14c.

N-type RESURF layers 16a, 16b, and 16c are formed between the p-type RESURF region 13 and the p-type guard ring layer 14a, between the p-type guard ring layers 14a and 14b, and between the p-type guard ring layers 14b and 14c, respectively. An n-type RESURF layer 17 is formed between the p-type guard ring layer 14c and the n⁺⁺-type EQPR layer 15. The n-type RESURF layer 17 is formed to have an impurity concentration Nd_{E} higher than the impurity concentrations Nd_{G1}=Nd_{G2}=Nd_{G3} of the n-type RESURF layers 16a, 16b, and 16c. Also, to suppress the influence of external charges, the n-type RESURF layers 16a, 16b, 16c and 17 are formed to have an impurity concentration higher than an impurity concentration of the n⁻ base layer 11 and lower than those of the p-type guard ring layers 14a, 14b, and 14c.

A p⁺ collector layer 19 is formed under the n⁻ base layer 11 via an n⁺ buffer layer 18 so that an insulated gate bipolar transistor (IGBT) element is configured in the cell portion 12.

Each layer may be formed by doping n-type or p-type impurities into a predetermined region of a silicon substrate, for example, a silicon epitaxial substrate in which an epitaxial layer doped with impurities is formed on a silicon substrate.

When a typically used guard ring structure is applied to a high-withstand-voltage element, a withstand voltage varies due to external charges accumulated at an interface between a substrate and a passivation film or oxide film formed on a surface of the substrate during a fabrication process. In particular, when extension of a depletion layer is promoted due to external charges during application of a reverse bias, an electric field concentrates on the periphery of a guard ring, thereby bringing about a drop in withstand voltage. In this case, by providing the n-type RESURF layers 16a, 16b, and 16c to suppress the extension of the depletion layer during the application of the reverse bias, electric field concentration, which occurs in the periphery of the guard ring, may be reduced to suppress the drop in withstand voltage.

In this case, when the depletion layer excessively extends at an outer circumferential side of the p-type guard ring layer 14c, there is a risk of element destruction due to the lattice defects of an outermost circumferential portion. Thus, the n-type RESURF layer 17 having a higher concentration than the n-type RESURF layers 16a, 16b, and 16c is provided between the p-type guard ring layer 14c and the n⁺⁺-type EQPR layer 15 to maximally suppress the extension of the depletion layer in an outer circumferential direction.

According to the present embodiment, the n-type RESURF layers 16a, 16b, and 16c are provided among the guard rings, and the n-type RESURF layer 17 having a higher concentration than the n-type RESURF layers 16a, 16b, and 16c is formed between the outermost p-type guard ring layer 14c and the n⁺⁺-type EQPR layer 15. Thus, when the accumulated external charges is the negative charges and the extension of the depletion layer is promoted in the periphery of the guard ring during application of a reverse bias, the extension of the depletion layer at a peripheral edge of a chip may be suppressed during the application of the reverse bias. As a result, element destruction of the peripheral edge due to the extension of the depletion layer in an outer circumferential direction of the element can be suppressed. Accordingly, a withstand voltage of the entire element can be improved.

### Second Embodiment

The present embodiment has the same configuration as the first embodiment except that concentrations of RESURF layers disposed inside respective guard ring layers and an EQPR layer are gradually increased toward an outer circumferential side.

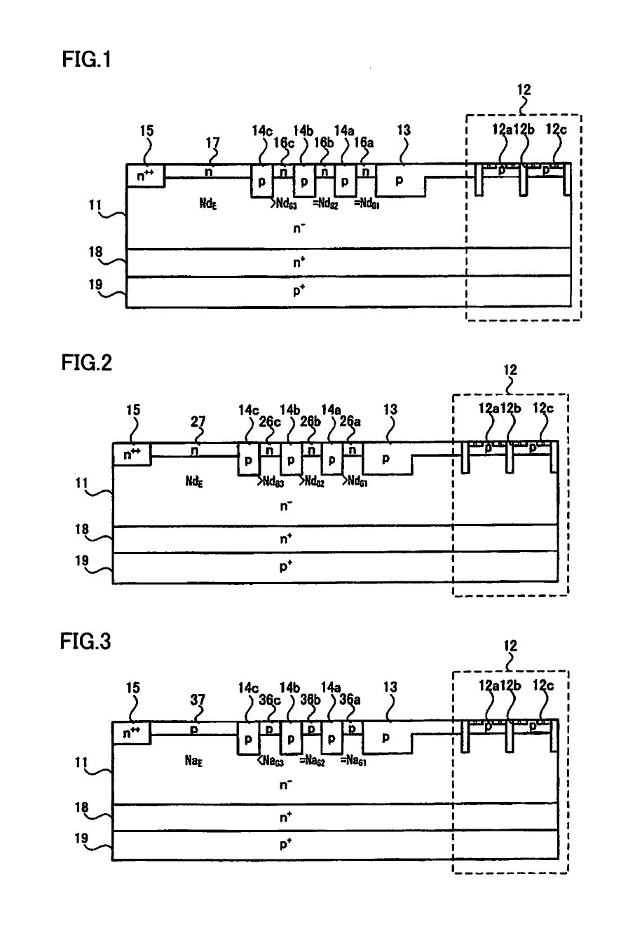

FIG. 2 is a cross-sectional view of a termination structure of a semiconductor device according to the present embodiment. In the drawings, the same reference numerals are used to denote the same components as in FIG. 1. N-type RESURF layers 26a, 26b, and 26c are formed between a p-type RESURF region 13 and a p-type guard ring layer 14a, between p-type guard ring layers 14a and 14b, and between p-type guard ring layers 14b and 14c, respectively. An n-type RESURF layer 27 is formed between the p-type guard ring layer 14c and an n⁺⁺-type EQPR layer 15. An impurity concentration Nd_{E} of the n-type RESURF layer 27 and the impurity concentrations Nd_{G1}, Nd_{G2}, and Nd_{G3} of the n-type RESURF layers 26a, 26b, and 26c are gradually increased in an outer circumferential direction, that is, Nd_{G3}<Nd_{G2}<Nd_{G1}<Nd_{E}, and are formed to be higher than an impurity concentration of an n⁻ base layer 11 and lower than the impurity concentrations of the p-type guard ring layers 14a, 14b, and 14c.

According to the present embodiment, when external charges are applied on the surface of the semiconductor device, which suppress the extension of a depletion layer during application of a reverse bias, a drop in withstand voltage due to the external charges in the periphery of a guard ring can be suppressed since the concentrations of the n-type RESURF layers are gradually increased in the outer circumferential direction as in the first embodiment. Further, the element destruction of a peripheral edge due to extension of the depletion layer in the outer circumferential direction can be more effectively suppressed.

When a variation in extension of the depletion layer occurs, the extension of the depletion layer can be made uniform by increasing or reducing the impurity concentrations of some of the n-type RESURF layers 26a, 26b, and 26c.

### Third Embodiment

The present embodiment has the same configuration as the first embodiment except that RESURF layers disposed inside respective guard ring layers and an EQPR layer have a p-type, which is an opposite conductivity type to a conductivity type of a base layer.

FIG. 3 is a cross-sectional view of a termination structure of a semiconductor device according to the present embodiment. P-type RESURF layers 36a, 36b, and 36c are formed between a p-type RESURF region 13 and a p-type guard ring layer 14a, between p-type guard ring layers 14a and 14b, and between p-type guard ring layers 14b and 14c, respectively. A p-type RESURF layer 37 is formed between the p-type guard ring layer 14c and an n⁺⁺-type EQPR layer 15. An impurity concentration Na_{E} of the p-type RESURF layer 37 is lower than impurity concentrations Na_{G1}, Na_{G2}, and Na_{G3} (Na_{G1}=Na_{G2}=Na_{G3}) of the p-type RESURF layers 36a, 36b, and 36c. Also, all the impurity concentrations Na_{E}, Na_{G1}, Na_{G2}, and Na_{G3} of the p-type RESURF layers 37, 36a, 36b, and 36c are formed to be higher than that of an n⁻ base layer 11 and lower than those of the p-type guard ring layers 14a, 14b, and 14c.

According to the present embodiment, when the external charges are accumulated on the surface of the semiconductor device, which suppress the extension of a depletion layer, the depletion layer may be extended by providing the p-type RESURF layers 36a, 36b, 36c, and 37.

In this case, when the depletion layer excessively extends at an outer circumferential side of the p-type guard ring layer 34c, the element destruction is likely to occur due to the lattice defects of an outermost circumferential portion. Thus, the p-type RESURF layer 37 having a lower concentration than the p-type RESURF layers 36a, 36b, and 36c is provided between the p-type guard ring layer 34c and the n⁺⁺-type EQPR layer 35, thereby suppressing the extension of the depletion layer in an outer circumferential direction.

According to the present embodiment, a withstand voltage of the periphery of a guard ring can be increased and, and the element destruction of a peripheral edge due to the extension of the depletion layer in an outer circumferential direction can be suppressed by providing the p-type RESURF layers 36a, 36b, 36c, and 37 and, particularly, lowering the concentration of the p-type RESURF layer 37 formed between the p-type guard ring layer 14c and the n⁺⁺-type EQPR layer 15.

### Fourth Embodiment

The present embodiment has the same configuration as the third embodiment except that concentrations of RESURF layers disposed inside respective guard ring layers and an EQPR layer are gradually reduced toward an outer circumferential side.

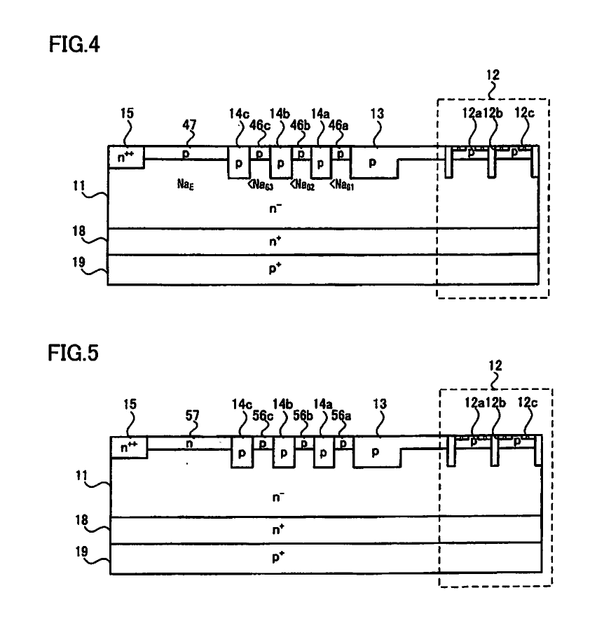

FIG. 4 is a cross-sectional view of a termination structure of a semiconductor device according to the present embodiment. P-type RESURF layers 46a, 46b, and 46c are formed between a p-type RESURF region 13 and a p-type guard ring layer 14a, between p-type guard ring layers 14a and 14b, and between p-type guard ring layers 14b and 14c, respectively. A p-type RESURF layer 47 is formed between the p-type guard ring layer 14c and an n⁺⁺-type EQPR layer 15. An impurity concentration Na_{E} of the n-type RESURF layer 47 and the impurity concentrations Na_{G1}, Na_{G2}, and Na_{G3} of the p-type RESURF layers 46a, 46b, and 46c are gradually reduced in an outer circumferential direction, that is, Na_{G3}>Na_{G2}>Na_{G1}>Na_{E}. Further, all the impurity concentrations Na_{E}, Na_{G1}, Na_{G2}, and Na_{G3} of the p-type RESURF layers 47, 46a, 46b, and 46c are formed to be higher than an impurity concentration of an n⁻ base layer 11 and lower than the impurity concentrations of the p-type guard ring layers 14a, 14b, and 14c.

According to the present embodiment, when external charges are applied on the surface of the semiconductor device, which suppress the extension of a depletion layer during application of a reverse bias, the withstand voltage of the periphery of the guard ring can be increased as in the third embodiment, since the concentrations of the p-type RESURF layers are gradually reduced in the outer circumferential direction.

Further, the element destruction of a peripheral edge due to extension of the depletion layer in the outer circumferential direction can be effectively suppressed.

When a variation in the extension of the depletion layer occurs, the extension of the depletion layer can be made uniform by increasing or decreasing the impurity concentrations of some of the n-type RESURF layers 26a, 26b, and 26c.

### Fifth Embodiment

The present embodiment has the same configuration as the first embodiment except that RESURF layers disposed inside respective guard ring layers have a different conductivity type from a RESURF layer interposed between a guard ring layer and an EQPR layer.

FIG. 5 is a cross-sectional view of a termination structure of a semiconductor device according to the present embodiment. P-type RESURF layers 56a, 56b, and 56c are formed between a p-type RESURF region 13 and a p-type guard ring layer 14a, between p-type guard ring layers 14a and 14b, and between p-type guard ring layers 14b and 14c, respectively. An n-type RESURF layer 57 is formed between the p-type guard ring layer 14 and an n⁺⁺-type EQPR layer 15. All impurity concentrations of the p-type RESURF layers 56a, 56b, and 56c and the n-type RESURF layer 57 are formed to be higher than an impurity concentration of an n⁻ base layer 11 and lower than the impurity concentrations of the p-type guard ring layers 14a, 14b, and 14c.

According to the present embodiment, when external charges are applied on the surface of the semiconductor device, which suppress the extension of a depletion layer during application of a reverse bias, a withstand voltage of the periphery of a guard ring can be increased and, further, the element destruction of a peripheral edge due to the extension of the depletion layer in an outer circumferential direction can be suppressed, since p-type RESURF layers are formed inside guard ring layers, and an n-type RESURF layer is formed between a guard ring layer and an EQPR layer.

### Sixth Embodiment

The present embodiment has the same configuration as the first embodiment except that each of RESURF layers disposed inside respective guard layers and between a guard ring layer and an EQPR layer has a two-layer structure of upper and lower layers having different conductivity types.

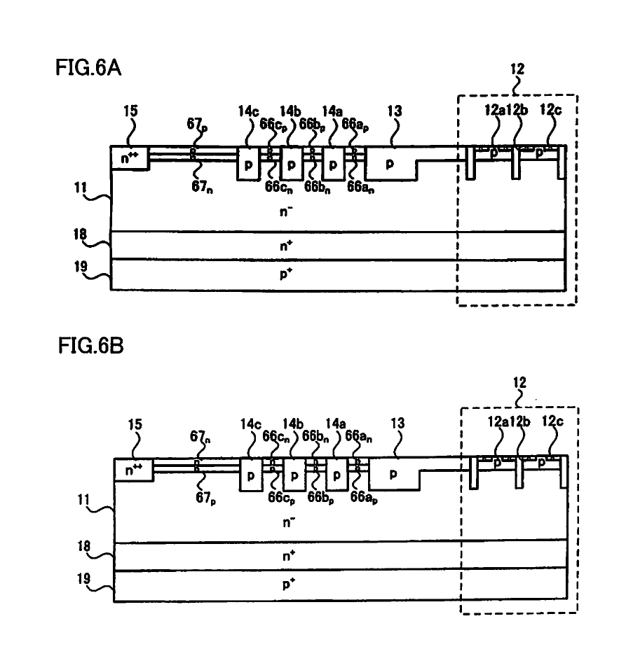

FIG. 6A is a cross-sectional view of a termination structure of a semiconductor device according to the present embodiment. Unlike in the first embodiment, RESURF layers having two-layer structures 66aₚ/66aₙ, 66bₚ/66bₙ, 66cₚ/66cₙ, and 67ₚ/67ₙ are formed between a p-type RESURF region 13 and a p-type guard ring layer 14a, between the p-type guard ring layers 14a and 14b, between the p-type guard ring layers 14b and 14c, and between the p-type guard ring layer 14c and an n⁺⁺-type EQPR layer 15, respectively. P-type RESURF layers 66aₚ, 66bₚ, 66cₚ, and 67ₚ are formed in a shallow region (surface side), while n-type RESURF layers 66aₙ, 66bₙ, 66cₙ, and 67ₙ are formed in a deep region.

According to the present embodiment, each of the RESURF layers disposed inside the guard ring layers and between the guard ring layer and the EQPR layer has a two-layer structure of p-type/n-type. Thus, as in the first embodiment, a drop in withstand voltage due to external charges can be suppressed in the periphery of a guard ring, and the element destruction of a peripheral edge due to extension of a depletion layer in an outer circumferential direction can be suppressed.

Further, as compared with a case where only one layer is formed, an impurity concentration may be particularly adjusted to a low concentration. Additionally, as shown in FIG. 6B, by reversing the conductivity type so that each of RESURF layers has a two-layer structure of n-type/p-type, the same effects can be obtained.

Even if each of the RESURF layers has the same conductivity type and concentration of impurities as in the second to fourth embodiment, the same effects as in the second to fourth embodiments can be obtained.

### Seventh Embodiment

The present embodiment has the same configuration as the first embodiment except that each of RESURF layers disposed between guard ring layers and between a guard ring layer and an EQPR layer is separated into a plurality of portions and partially formed.

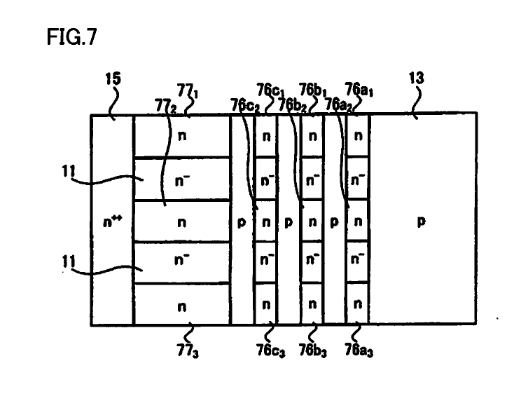

FIG. 7 is a top view of a termination structure of a semiconductor device according to the present embodiment. Separated n-type RESURF layers 76a₁, 76a₂, 76a₃ . . . , 76b₁, 76b₂, 76b₃ . . . , 76c₁, 76c₂, 76c₃ . . . , and 77₁, 77₂, 77₃ . . . are formed between a p-type RESURF region 13 and a p-type guard ring layer 14a, between the p-type guard ring layers 14a and 14b, between the p-type guard ring layers 14b and 14c, and between the p-type guard ring layer 14c and an n⁺⁺-type EQPR layer 15, respectively. The respective n-type RESURF layers are formed at right angles to the p-type guard ring layers 14a, 14b, and 14c and the n⁺⁺-type EQPR layer 15.

According to the present embodiment, each of the n-type RESURF layers disposed between the guard ring layers and between the guard ring layer and the EQPR layer is separated into a plurality of portions and partially formed. Thus, as in the first embodiment, a drop in withstand voltage due to external charges can be suppressed in the periphery of a guard ring, and the element destruction of a peripheral edge due to extension of a depletion layer in an outer circumferential direction can be suppressed. Further, as compared with a case where each of the RESURF layers is not separated, the extension of the depletion layer along a direction perpendicular to the outer circumferential direction can be appropriately controlled.

Even if each of the RESURF layers has the same conductivity type and concentration of impurities as in the second to the fourth embodiments, the same effects as in the second to the fourth embodiments can be obtained.

In the above-described embodiments, a diffusion length in a lateral direction of a guard ring layer is preferably adjusted to about 0.8 times or less a diffusion length in a vertical direction of the guard ring layer. By adjusting the diffusion length in the lateral direction of the guard ring layer to about 0.8 times or less, more precise design of guard rings may be enabled.

Furthermore, although the above-described embodiments describe that the cell portion 12 is the IGBT element, the present invention is not limited thereto, and other elements, such as a power metal-oxide-semiconductor field-effect transistor (MOSFET), a diode, or a thyristor, may be applied to the cell portion 12. Additionally, the present invention is not limited to a silicon semiconductor and may be applied to a compound semiconductor, such as a silicon carbide (SiC) semiconductor.

Each of the structures included in the above-described embodiments may be appropriately selected in consideration of an applied device, a purpose, and a required withstand voltage. Accordingly, although the design for the withstand voltage has been in consideration of only the number and dimension of the guard rings, a degree of freedom for design can be improved.

In addition, although the above-described embodiments provide the n⁻-type base layer, the base layer may be provided as a p-type, and a conductivity type of each layer may be reversed accordingly.

While the present invention has been described in connection with several exemplary embodiments thereof, these are intended merely as illustrative examples, and the scope of the invention is not limited thereto. These embodiments can be implemented in other various forms, and are capable of various omissions, changes, and modifications without departing from the spirit and scope of the invention. Rather, such exemplary embodiments and modifications thereof are included in the scope and spirit of the present invention corresponding to the invention defined by the following claims.

What is claimed is:

1. A semiconductor device comprising:
a base semiconductor layer of a first conductivity type;
a cell portion including a diffusion region of a second conductivity type formed on a surface of the base semiconductor layer;
a plurality of guard ring semiconductor layers of the second conductivity type formed on the surface of the base semiconductor layer, each guard ring semiconductor layer being formed to surround the cell portion;
an equivalent-potential ring (EQPR) semiconductor layer of the first conductivity type formed on a surface of an outer circumferential portion of the base semiconductor layer spaced apart from an outermost guard ring semiconductor layer of the plurality of guard ring semiconductor layers in an outer circumferential direction, the EQPR semiconductor layer having a higher concentration than the first semiconductor layer and a lower concentration than the guard ring semiconductor layer;
a plurality of first RESURF semiconductor layers of the first conductivity type provided on the surface of the base semiconductor layer inside the plurality of guard ring semiconductor layers and having a higher concentration than the base semiconductor layer; and
a second RESURF semiconductor layer of the first conductivity type provided on the surface of the base semiconductor layer between the outermost guard ring semiconductor layer and the EQPR semiconductor layer, the second RESURF semiconductor layer having a higher impurity concentration than the first RESURF semiconductor layers.

2. The semiconductor device according to claim 1, wherein the cell portion comprises:
a trench gate formed to extend into the base semiconductor layer through the diffusion region of the second conductivity type;
an emitter layer of the first conductivity type formed on a surface of the diffusion region on both sides of the trench gate;
a buffer semiconductor layer of the first conductivity type formed under the base semiconductor layer; and
a collector layer of the second conductivity type formed under the buffer semiconductor layer.

3. The semiconductor device according to claim 1, wherein the concentration of the plurality of first RESURF semiconductor layers increases toward an outer circumferential side.

4. The semiconductor device according to claim 1, wherein each of the first RESURF semiconductor layers or the second RESURF semiconductor layer has a stack structure of upper and lower layers having different conductivity types.

5. The semiconductor device according to claim 1, wherein the first conductivity type is an n-type, and the second conductivity type is a p-type.

6. A semiconductor device comprising:
a base semiconductor layer of a first conductivity type;
a cell portion including a diffusion region of a second conductivity type formed on a surface of the base semiconductor layer;
a plurality of guard ring semiconductor layers of the second conductivity type formed on the surface of the base semiconductor layer, each guard ring semiconductor layer being formed to surround the cell portion;
an equivalent-potential ring (EQPR) semiconductor layer of the first conductivity type formed on a surface of an outer circumferential portion of the base semiconductor layer spaced apart from an outermost guard ring semiconductor layer of the plurality of guard ring semiconductor layers in an outer circumferential direction, the EQPR semiconductor layer having a higher concentration than the first semiconductor layer and a lower concentration than the guard ring semiconductor layer;
a plurality of first RESURF semiconductor layers of the second conductivity type provided on the surface of the base semiconductor layer inside the plurality of guard ring semiconductor layers, the plurality of first RESURF semiconductor layers having a higher concentration than the base semiconductor layer; and
a second RESURF semiconductor layer of the second conductivity type provided on the surface of the base semiconductor layer between the outermost guard ring semiconductor layer and the EQPR semiconductor layer, the second RESURF semiconductor layer having a lower impurity concentration than the first RESURF semiconductor layer.

7. The semiconductor device according to claim 6, wherein the cell portion comprises:
a trench gate formed to extend into the base semiconductor layer through the diffusion region of the second conductivity type;
an emitter layer of the first conductivity type formed on a surface of the diffusion region on both sides of the trench gate;
a buffer semiconductor layer of the first conductivity type formed under the base semiconductor layer; and
a collector layer of the second conductivity type formed under the buffer semiconductor layer.

8. The semiconductor device according to claim 6, wherein the concentration of the plurality of first RESURF semiconductor layers decreases toward an outer circumferential side.

9. The semiconductor device according to claim 6, wherein the first RESURF semiconductor layer or the second RESURF semiconductor layer has a stacked structure of upper and lower layers having different conductivity types.

10. The semiconductor device according to claim 6, wherein the first conductivity type is an n-type, and the second conductivity type is a p-type.

11. A semiconductor device comprising:
a base semiconductor layer of a first conductivity type;
a cell portion including a diffusion region of a second conductivity type formed on a surface of the base semiconductor layer;
a plurality of guard ring semiconductor layers of the second conductivity type formed on the surface of the base semiconductor layer, each guard ring semiconductor layer being formed to surround the cell portion;
an equivalent-potential ring (EQPR) semiconductor layer of the first conductivity type formed on a surface of an outer circumferential portion of the base semiconductor layer spaced apart from an outermost guard ring semiconductor layer of the plurality of guard ring semiconductor layers in an outer circumferential direction, the EQPR semiconductor layer having a higher concentration than the first semiconductor layer and a lower concentration than the guard ring semiconductor layer;
a plurality of first RESURF semiconductor layers of the second conductivity type provided on the surface of the base semiconductor layer inside the plurality of guard ring semiconductor layers, the plurality of first RESURF semiconductor layers having a higher concentration than the base semiconductor layer; and
a second RESURF semiconductor layer of the first conductivity type provided on the surface of the base semiconductor layer between the outermost guard ring semiconductor layer and the EQPR semiconductor layer.

12. The semiconductor device according to claim 11, wherein the cell portion comprises:
a trench gate formed to extend into the base semiconductor layer through the diffusion region of the second conductivity type;
an emitter layer of the first conductivity type formed on a surface of the diffusion region on both sides of the trench gate;
a buffer semiconductor layer of the first conductivity type formed under the base semiconductor layer; and
a collector layer of the second conductivity type formed under the buffer semiconductor layer.

13. The semiconductor device according to claim 11, wherein the first RESURF semiconductor layer or the second RESURF semiconductor layer has a stacked structure of upper and lower layers having different conductivity types.

14. The semiconductor device according to claim 11, wherein the first conductivity type is an n-type, and the second conductivity type is a p-type.

15. A semiconductor device comprising:
a base semiconductor layer of a first conductivity type;
a cell portion including a diffusion region of a second conductivity type formed on a surface of the base semiconductor layer;
a plurality of guard ring semiconductor layers of the second conductivity type formed on the surface of the base semiconductor layer, each guard ring semiconductor layer being formed to surround the cell portion;
an equivalent-potential ring (EQPR) semiconductor layer of the first conductivity type formed on a surface of an outer circumferential portion of the base semiconductor layer spaced apart from an outermost guard ring semiconductor layer of the plurality of guard ring semiconductor layers in an outer circumferential direction, the EQPR semiconductor layer having a higher concentration than the first semiconductor layer and a lower concentration than the guard ring semiconductor layer;
a first RESURF semiconductor layer provided on the surface of the base semiconductor layer inside the plurality of guard ring semiconductor layers; and
a second RESURF semiconductor layer provided on the surface of the base semiconductor layer between the outermost guard ring semiconductor layer and the EQPR semiconductor layer,
wherein in response to external charges accumulated on the surface of the base semiconductor layer, conductivity types and concentrations of impurities of the first and second RESURF semiconductor layers are selected such that, during application of a reverse bias, the first RESURF semiconductor layer facilitates formation of a depletion layer in a region where the plurality of guard ring semiconductor layers are formed, while the second RESURF semiconductor layer suppresses the formation of the depletion layer in a region between the outermost guard ring semiconductor layer and the EQPR semiconductor layer.

16. The semiconductor device according to claim 15, wherein the cell portion comprises:
a trench gate formed to extend into the base semiconductor layer through the diffusion region of the second conductivity type;
an emitter layer of the first conductivity type formed on a surface of the diffusion region on both sides of the trench gate;
a buffer semiconductor layer of the first conductivity type formed under the base semiconductor layer; and
a collector layer of the second conductivity type formed under the buffer semiconductor layer.

17. The semiconductor device according to claim 15, wherein the concentration of the plurality of first RESURF semiconductor layers increases toward an outer circumferential side.

18. The semiconductor device according to claim 15, wherein the first RESURF semiconductor layer or the second RESURF semiconductor layer has a stacked structure of upper and lower layers having different conductivity types.

19. The semiconductor device according to claim 15, wherein the first conductivity type is an n-type, and the second conductivity type is a p-type.
